(19) United States
(12) Patent Application Publication
(10) Pub. No.: US 2026/0130096 A1
(43) Pub. Date: May 7, 2026

(54) DISPLAY PANEL AND ELECTRONIC DEVICE INCLUDING THE SAME

(71) Applicant: SAMSUNG DISPLAY CO., LTD., YONGIN-SI (KR)

(72) Inventors: CHANGYEONG SONG, Yongin-si (KR); Jinyoung KOO, Yongin-si (KR); YEONGUK KIM, Yongin-si (KR); HEEYEON PARK, Yongin-si (KR); GIHOON YANG, Yongin-si (KR); Hyein JUNG, Yongin-si (KR); YONGCHAN JU, Yongin-si (KR); JAEHEUNG HA, Yongin-si (KR)

(21) Appl. No.: 19/374,685

(22) Filed: Oct. 30, 2025

(30) Foreign Application Priority Data
Nov. 4, 2024 (KR) 10-2024-0153988

(51) Int. Cl. H10K 59/80; H10K 59/40

(52) U.S. Cl. CPC H10K 59/873; H10K 59/40

(57) ABSTRACT

A display panel includes a base layer, a circuit layer disposed on the base layer, a light emitting element layer including a light emitting element and disposed on the circuit layer, and an encapsulation layer disposed on the light emitting element layer and including a first inorganic layer, an organic layer disposed on the first inorganic layer, and a second inorganic layer disposed on the organic layer. The organic layer includes a covalent organic framework.

### CROSS-REFERENCE TO RELATED APPLICATION(S)

This U.S. patent application claims priority under 35 U.S.C. § 119 to Korean Patent Application No. 10-2024-0153988, filed on Nov. 4, 2024 in the Korean Intellectual Property Office, the disclosure of which is incorporated by reference in its entirety herein.

### 1. TECHNICAL FIELD

The present disclosure is directed to a display panel and an electronic device including the same. More particularly, the present disclosure is directed to a display panel including an encapsulation layer that covers a light emitting element and an electronic device including the display panel.

### 2. DISCUSSION OF RELATED ART

Various types of light emitting display devices have been developed to meet increasing demands for high-resolution, high-efficiency, and flexible display technologies. These include organic light emitting diode (OLED) displays, inorganic light emitting displays, hybrid organic-inorganic light emitting displays, quantum dot displays, micro-light emitting diode (micro-LED) displays, and nano-light emitting diode (nano-LED) displays. OLED and hybrid displays are known for their excellent color reproduction and thin form factor, making them well-suited for mobile and wearable devices. Inorganic and micro-LED displays offer high brightness, durability, and energy efficiency, making them attractive for larger-scale applications such as televisions and digital signage. Quantum dot and nano-LED displays leverage quantum confinement effects to achieve superior color purity and brightness.

An electronic device may include one of these display devices, and thus may include an active area activated in response to electrical signals. The active area typically includes light emitting elements and may perform dual functions, displaying images and detecting external inputs, such as pressure, thereby enabling the device to present information to a user while supporting interactive functionality.

The light emitting elements may include organic light emitting materials or quantum dot light emitting materials, which are highly susceptible to oxygen and moisture. Infiltration of these substances can cause various defects occur in the light emitting elements. Accordingly, ongoing research focuses on developing encapsulation layers to protect these components from environmental degradation.

### SUMMARY

At least one embodiment of the present disclosure provides a display panel that includes a sensor layer with enhanced touch sensitivity and a structure that reduces dead space and electronic device including the display panel.

Embodiments of the inventive concept provide a display panel including a base layer, a circuit layer disposed on the base layer, a light emitting element layer including a light emitting element and disposed on the circuit layer, and an encapsulation layer disposed on the light emitting element layer and including a first inorganic layer, an organic layer disposed on the first inorganic layer, and a second inorganic layer disposed on the organic layer. The organic layer includes a covalent organic framework.

In an embodiment, the organic layer has a dielectric constant greater than or equal to about 1.2 and smaller than or equal to about 2.5.

In an embodiment, the organic layer has a modulus greater than or equal to about 0.01 gigapascal (GPa) and smaller than or equal to about 4 GPa.

In an embodiment, the display panel comprises an active area where the light emitting element is disposed and a peripheral area surrounding the active area, wherein an edge of the organic layer is disposed outside the active area when viewed in a plane, and the edge of the organic layer is disposed inside each of an edge of the first inorganic layer and an edge of the second inorganic layer when viewed in the plane.

In an embodiment, the organic layer has a thickness greater than or equal to about 0.2 micrometer (μm) and smaller than or equal to about 20 μm.

In an embodiment, each of the first and second inorganic layers includes silicon oxide, silicon nitride, or silicon oxynitride.

In an embodiment, the organic layer is formed through a vapor deposition process.

In an embodiment, the covalent organic framework includes a benzene ring.

In an embodiment, the covalent organic framework includes an oxo group, an amino group, or a cyano group.

Embodiments of the inventive concept provide an electronic device including a display panel including a light emitting element and a sensor layer disposed on the display panel and for sensing an external input. The display panel includes a base layer, a circuit layer disposed on the base layer, a light emitting element layer including the light emitting element and disposed on the circuit layer, and an encapsulation layer disposed on the light emitting element layer and including a first inorganic layer, an organic layer disposed on the first inorganic layer, and a second inorganic layer disposed on the organic layer. The organic layer includes a covalent organic framework.

In an embodiment, the organic layer has a dielectric constant greater than or equal to about 1.2 and smaller than or equal to about 2.5.

In an embodiment, the organic layer has a modulus greater than or equal to about 0.01 GPa and smaller than or equal to about 4 GPa.

In an embodiment, the display panel comprises an active area where the light emitting element is disposed and a peripheral area surrounding the active area, wherein an edge of the organic layer is disposed outside the active area when viewed in a plane, and the edge of the organic layer is disposed inside each of an edge of the first inorganic layer and an edge of the second inorganic layer when viewed in the plane.

In an embodiment, the organic layer has a thickness greater than or equal to about 0.2 μm and smaller than or equal to about 20 μm.

In an embodiment, each of the first and second inorganic layers includes silicon oxide, silicon nitride, or silicon oxynitride.

In an embodiment, the organic layer is formed through a vapor deposition process.

In an embodiment, the covalent organic framework includes a benzene ring.

In an embodiment, the covalent organic framework includes an oxo group, an amino group, or a cyano group.

In an embodiment, the sensor layer is disposed directly on the second inorganic layer.

The electronic device further includes a window disposed on the sensor layer.

Embodiments of the inventive concept provide a display panel including a base layer, a circuit layer disposed on the base layer, a light emitting element layer including a light emitting element and disposed on the circuit layer, and an encapsulation layer disposed on the light emitting element layer and including a first inorganic layer, an organic layer disposed on the first inorganic layer, and a second inorganic layer disposed on the organic layer. The organic layer comprises a porous organic material including a benzene ring and at least one of an oxo group, an amino group, or a cyano group.

When the encapsulation layer of the display panel includes the covalent organic framework (COF), a dam structure is unnecessary, and thus, a dead space of the display panel may be reduced.

A touch sensitivity of the electronic device may be enhanced when an encapsulation layer of the display panel including the covalent organic framework (COF) has low dielectric constant properties. In addition, the encapsulation layer of the display panel need not include the dam structure, and thus, the dead space of the electronic device may be reduced.

### BRIEF DESCRIPTION OF THE DRAWINGS

FIG. 1 is an assembled perspective view of an electronic device according to an embodiment of the present disclosure;

FIG. 2 is an exploded perspective view of an electronic device according to an embodiment of the present disclosure;

FIG. 3 is a cross-sectional view of an electronic device according to an embodiment of the present disclosure;

FIG. 4 is a cross-sectional view of an electronic device according to an embodiment of the present disclosure;

FIG. 5 is a cross-sectional view of a portion of an electronic device according to an embodiment of the present disclosure;

FIG. 6 is a cross-sectional view of a portion of an electronic device according to an embodiment of the present disclosure;

FIG. 7 is a cross-sectional view of a portion of a display module according to an embodiment of the present disclosure; and

FIG. 8 is a block diagram an the electronic according to an embodiment of the disclosure.

### DETAILED DESCRIPTION

The present disclosure may be variously modified and realized in many different forms, and thus specific embodiments will be exemplified in the drawings and described in detail hereinbelow. However, the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

In the present disclosure, when an element is referred to as being “directly disposed” to another element, there are no intervening elements present between a layer, film region, or substrate and another layer, film, region, or substrate. For example, the term “directly disposed” may mean that two layers or two members are disposed without employing additional adhesive therebetween.

Like numerals refer to like elements throughout. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

At least one embodiment relates to a display panel and an electronic device including the same, and more particularly, to an encapsulation structure that enhances both display performance and device integration. The display panel includes a base layer, a circuit layer, a light emitting element layer, and an encapsulation layer formed over the light emitting element layer to protect it from external contaminants such as moisture and oxygen. To address demands for higher touch sensitivity and reduced peripheral dead space, the encapsulation layer includes a multi-layer structure including a first inorganic layer, an organic layer, and a second inorganic layer.

In particular embodiment, the organic layer includes a covalent organic framework (COF), which offers a stable porous structure formed by covalent bonding between organic precursors. The COF may include structural features such as benzene rings and functional groups like oxo (═O), amino (—NH₂), or cyano (—CN), resulting in a low dielectric constant and a relatively high mechanical modulus. These characteristics allow the COF layer to be vapor-deposited, eliminating the need for conventional dam structures at the panel edge and thereby minimizing dead space (i.e., a portion of the display surface that does not emit light or respond to touch input). As a result, the display panel can achieve enhanced touch sensitivity, enhanced mechanical durability, and a more compact form factor suitable for next-generation electronic devices

Hereinafter, a display panel and an electronic device according to embodiments of the present disclosure will be described with reference to accompanying drawings.

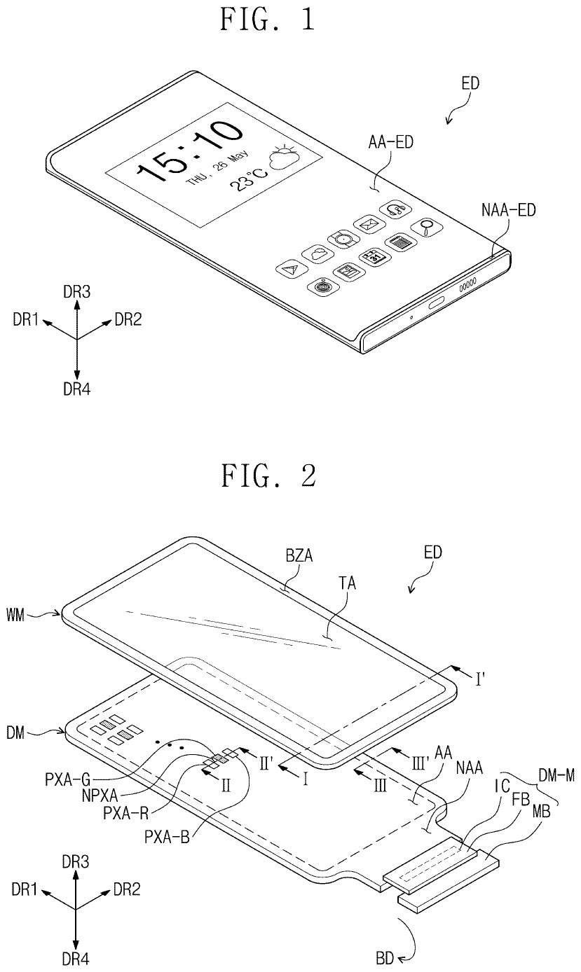

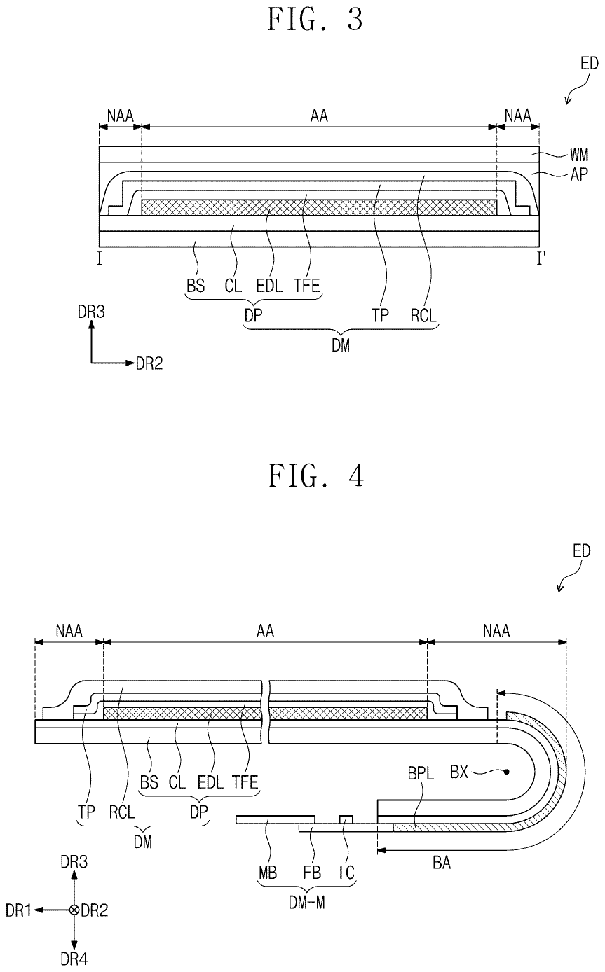

FIG. 1 is an assembled perspective view of an electronic device ED according to an embodiment of the present disclosure. FIG. 2 is an exploded perspective view of an electronic device ED according to an embodiment of the present disclosure. FIGS. 3 and 4 are cross-sectional views of an electronic device according to an embodiment of the present disclosure.

The electronic device ED shown in FIGS. 1 to 4 may be activated in response to electrical signals. As an example, the electronic device ED may be a mobile phone, a tablet computer, a monitor, a television set, a car navigation unit, a game unit, or a wearable device, however, it should not be limited thereto or thereby. FIG. 1 shows the mobile phone as a representative example of the electronic device ED.

The electronic device ED may display an image through an active area AA-ED. The active area AA-ED may include a plane defined by a first direction DR1 and a second direction DR2. The active area AA-ED may further include a curved surface bent from at least one side of the plane defined by the first direction DR1 and the second direction DR2.

A peripheral area NAA-ED may be defined adjacent to the active area AA-ED. The peripheral area NAA-ED may surround the active area AA-ED. Accordingly, the active area AA-ED may have a shape defined by the peripheral area NAA-ED. However, this is merely an example, and the peripheral area NAA-ED may be disposed adjacent to only one side of the active area AA-ED or may be omitted. The active area AA-ED of the electronic device ED may have a variety of shapes and is not limited thereto.

The electronic device ED shown in FIG. 1 may include two curved surfaces respectively bent from opposite sides of the plane defined by the first direction DR1 and the second direction DR2. However, the shape of the active area AA-ED should not be limited thereto or thereby. For example, the active area AA-ED may include only the plane, or the active area AA-ED may include curved surfaces respectively bent from at least two sides of the plane, that is, the active area AA-ED may include four curved surfaces respectively bent from four sides of the plane.

In FIG. 1 and accompanying drawings, the first to fourth directions DR1 to DR4 are shown, and directions respectively indicated by the first to fourth directions DR1 to DR4 may be relative to each other and may be changed in other directions.

In the present disclosure, the first direction DR1 may be substantially perpendicular to the second direction DR2, and the third direction DR3 may be a normal line direction with respect to the plane defined by the first direction DR1 and the second direction DR2. The fourth direction DR4 may be a normal line direction with respect to the plane defined by the first direction DR1 and the second direction DR2 and may be opposite to the third direction DR3.

A thickness direction of the electronic device ED may be substantially parallel to the third direction DR3 that is the normal line direction of the plane defined by the first direction DR1 and the second direction DR2. In the present disclosure, front (or upper) and rear (or lower) surfaces of each member of the electronic device ED may be defined in the third direction DR3.

In the present disclosure, the expression ‘when viewed in a plane’ means a state of being viewed from a plane defined by the first and second directions DR1 and DR2. In the present disclosure, the term ‘overlap’ refers to overlapping when viewed in the plane, unless otherwise specified.

The electronic device ED may include a display module DM. The display module DM may generate the image and sense a pressure applied thereto from the outside. The display module DM may include a display panel DP. The display module DM may further include a sensor layer TP disposed on the display panel DP and an optical layer RCL disposed on the sensor layer TP. However, the present disclosure should not be limited thereto or thereby, and the sensor layer TP or the optical layer RCL may be omitted according to embodiments.

The display module DM may include an active area AA and a peripheral area NAA. The active area AA may be activated in response to electrical signals. The peripheral area NAA may be defined adjacent to at least one side of the active area AA.

The active area AA may correspond to the active area AA-ED of the electronic device ED shown in FIG. 1. The peripheral area NAA may correspond to the peripheral area NAA-ED of the electronic device ED shown in FIG. 1.

Referring to FIG. 2, the active area AA may include a plurality of light emitting areas PXA-R, PXA-G, and PXA-B. As an example, the electronic device ED may include a first light emitting area PXA-R, a second light emitting area PXA-G, and a third light emitting area PXA-B. The first light emitting area PXA-R may be a red light emitting area emitting a red light, the second light emitting area PXA-G may be a green light emitting area emitting a green light, and the third light emitting area PXA-B may be a blue light emitting area emitting a blue light.

When viewed in the plane, the first, second, and third light emitting areas PXA-R, PXA-G, and PXA-B may be distinguished from each other without overlapping each other. As an example, a non-light-emitting area NPXA may be disposed between the light emitting areas PXA-R, PXA-G, and PXA-B adjacent to each other.

FIG. 2 shows the light emitting areas PXA-R, PXA-G, and PXA-B arranged in a stripe form as a representative example. That is, as shown in the electronic device ED shown in FIG. 2, the light emitting areas PXA-R, PXA-G, and PXA-B may be repeatedly arranged in the order of the first light emitting area PXA-R, the second light emitting area PXA-G, and the third light emitting area PXA-B.

The arrangement of the light emitting areas PXA-R, PXA-G, and PXA-B should not be limited to that shown in FIG. 2, and the order in which the first light emitting area PXA-R, the second light emitting area PXA-G, and the third light emitting area PXA-B are arranged may be provided in various combinations according to characteristics of a display quality required for the electronic device ED. As an example, the light emitting areas PXA-R, PXA-G, and PXA-B may be arranged in a pentile form such as PenTile™ or a diamond form such as Diamond Pixel™.

Sizes of the light emitting areas PXA-R, PXA-G, and PXA-B emitting lights having different wavelength ranges from each other may be different from each other. In this case, the sizes of the light emitting areas PXA-R, PXA-G, and PXA-B may mean sizes when viewed in the plane defined by the first direction DR1 and the second direction DR2. However, the present disclosure is not limited thereto. For example, according to an embodiment, the light emitting areas PXA-R, PXA-G, and PXA-B may have substantially the same size. In addition, a size ratio of the light emitting areas PXA-R, PXA-G, and PXA-B may be changed in various ways according to characteristics of the display quality required for the electronic device ED, and the shape of the light emitting areas PXA-R, PXA-G, and PXA-B when viewed in the plane may be changed in various ways.

As shown in FIG. 2, each of the light emitting areas PXA-R, PXA-G, and PXA-B may have a quadrangular shape. However, the present disclosure is not limited thereto. According to an embodiment, each of the light emitting areas PXA-R, PXA-G, and PXA-B may have a polygonal shape or a circular shape when viewed in the plane.

The peripheral area NAA may surround the active area AA. However, the present disclosure is not limited thereto. Different from the electronic device ED of FIG. 2, a portion of the peripheral area NAA may be omitted. A driving circuit or a driving line to drive the active area AA may be arranged in the peripheral area NAA.

Referring to FIG. 4, the peripheral area NAA may include a bending area BA bent about a bending axis BX extending in one direction. A bending portion protection layer BPL may be disposed in the bending area BA. The bending portion protection layer BPL may protect a circuit layer CL disposed in the peripheral area NAA. The bending portion protection layer BPL may prevent cracks from occurring in components included in the circuit layer CL exposed in the bending area BA. The bending portion protection layer BPL may include at least one of an acrylic-based polymer, a silicone-based polymer, and an imide-based polymer, however, the present disclosure should not be limited thereto or thereby.

Different from the electronic device ED shown in FIG. 4, the bending portion protection layer BPL may be connected to or overlap an edge of the optical layer RCL. In addition, some of the components of the optical layer RCL may extend to the bending area BA and may be provided as the bending portion protection layer BPL. In addition, the bending portion protection layer BPL may be omitted according to embodiments.

The display panel DP may be configured to generate images. The display panel DP may be a light emitting type display panel, for example, an organic light emitting display panel, an inorganic light emitting display panel, a quantum dot light emitting display panel, a micro-LED display panel, or a nano-LED display panel. Hereinafter, the organic light emitting display panel will be described as a representative example of the display panel DP.

FIG. 3 is a cross-sectional view taken along a line I-I′ of FIG. 2. Referring to FIGS. 3 and 4, the display panel DP may include a base layer BS, the circuit layer CL, a light emitting element layer EDL, and an encapsulation layer TFE.

The base layer BS may provide a base surface on which the circuit layer CL is disposed. The base layer BS may be a rigid substrate or a flexible substrate that is bendable, foldable, or rollable. The base layer BS may include a glass substrate, a metal substrate, or a polymer substrate, however, it should not be limited thereto or thereby. According to an embodiment, the base layer BS may be an inorganic layer, an organic layer, or a composite material layer.

The circuit layer CL may be disposed on the base layer BS. The circuit layer CL may include an insulating layer, a semiconductor pattern, a conductive pattern, and a signal line. An insulating layer, a semiconductor layer, and a conductive layer may be formed on the base layer BS by a coating or depositing process. Then, the insulating layer, the semiconductor layer, and the conductive layer may be selectively patterned through several photolithography processes. Thus, the semiconductor pattern, the conductive pattern, and the signal line of the circuit layer CL may be formed.

The light emitting element layer EDL may be disposed on the circuit layer CL. The light emitting element layer EDL may include the light emitting element. As an example, the light emitting element may include an organic light emitting material, an inorganic light emitting material, an organic-inorganic light emitting material, a quantum dot, a quantum rod, a micro-LED, or a nano-LED.

The encapsulation layer TFE may be disposed on the light emitting element layer EDL. The encapsulation layer TFE may cover the light emitting element layer EDL. The encapsulation layer TFE may be disposed in the active area AA where the light emitting element layer EDL is disposed and may extend to the peripheral area NAA where the light emitting element layer EDL is not disposed.

The encapsulation layer TFE may protect the light emitting element layer EDL from environmental factors such as moisture, oxygen, and a foreign substances, including dust particles. The encapsulation layer TFE will be described in detail later.

The sensor layer TP may be disposed on the display panel DP. The sensor layer TP may sense an external input applied from the outside. For example, the external input may be a user input. The user input may include a variety of forms of external inputs, such as a part of user's body, light, heat, pen, or pressure.

The sensor layer TP may be formed on the display panel DP through successive processes. In this case, the sensor layer TP may be disposed directly on the display panel DP. In the present embodiment, the expression “The sensor layer TP may be disposed directly on the display panel DP” may mean that a separate component is not disposed between the sensor layer TP and the display panel DP. That is, a separate adhesive member may not be disposed between the sensor layer TP and the display panel DP. As an example, the sensor layer TP may be disposed directly on the encapsulation layer TFE. The sensor layer TP may be coupled with the display panel DP by an adhesive member. The adhesive member may include a conventional adhesive.

The optical layer RCL may be disposed on the sensor layer TP. The optical layer RCL may be disposed directly on the sensor layer TP. The optical layer RCL may be formed on the sensor layer TP through successive processes. The optical layer RCL may reduce a reflectance of the display module DM with respect to external light incident on the display module DM. The optical layer RCL may include a polarizing layer or a color filter layer. According to an embodiment, the optical layer RCL may be omitted.

According to an embodiment of the present disclosure, the sensor layer TP may be omitted. In this case, the optical layer RCL may be disposed directly on the display panel DP. According to an embodiment, the positions of the sensor layer TP and the optical layer RCL may be switched. For example, the sensor layer and the optical layer may be arranged in reverse order, with the optical layer positioned below the sensor layer instead of above it.

The electronic device ED may further include a driver DM-M (e.g., a driver circuit) electrically connected to the display module DM. The driver DM-M may be electrically connected to the display panel DP and the sensor layer TP. The driver DM-M may include a driving chip IC. The driving chip IC may generate or process various electrical signals, and the driving chip IC may be electrically connected to the display panel DP and the sensor layer TP to control the display panel DP and the sensor layer TP.

The driver DM-M may include a flexible circuit board FB and a driving circuit board MB. One end of the flexible circuit board FB may be electrically connected to the display panel DP and the sensor layer TP, while the other end may be electrically connected to the driving circuit board MB. The driving chip IC may be disposed on the flexible circuit board FB. In this case, the flexible circuit board FB may be referred to as a chip-on-film (COF). In addition, different from the driving chip IC shown in FIG. 4, the driving chip IC may be disposed on the base layer BS of the display module DM.

FIG. 2 shows a structure in which the driver DM-M is connected to one side of the display module DM in an unfolded state; however, as shown in FIG. 4, the driver DM-M of the electronic device ED may be bent in the fourth direction DR4. Referring to FIG. 4, the driver DM-M may be bent and may overlap the display panel DP when viewed in the plane.

The electronic device ED may further include a window WM disposed on the display module DM. The window WM may cover a front surface of the display module DM. The window WM may be coupled with the display module DM by an adhesive layer AP.

The window WM may have a shape corresponding to a shape of the display module DM. The window WM of the electronic device ED may include an optically transparent insulating material. The window WM may include a glass substrate or polymer substrate. For instance, the window WM may be a chemically tempered glass substrate.

The window WM may include a transmission area TA and a bezel area BZA. The transmission area TA may correspond to the active area AA of the display module DM, and the bezel area BZA may correspond to the peripheral area NAA of the display module DM. The transmission area TA may have a shape defined by the bezel area BZA. The bezel area BZA may be disposed adjacent to the transmission area TA and may surround the transmission area TA. However, the present disclosure is not limited thereto, and according to an embodiment, the bezel area BZA may be disposed adjacent to only one side of the transmission area TA or may be partially omitted.

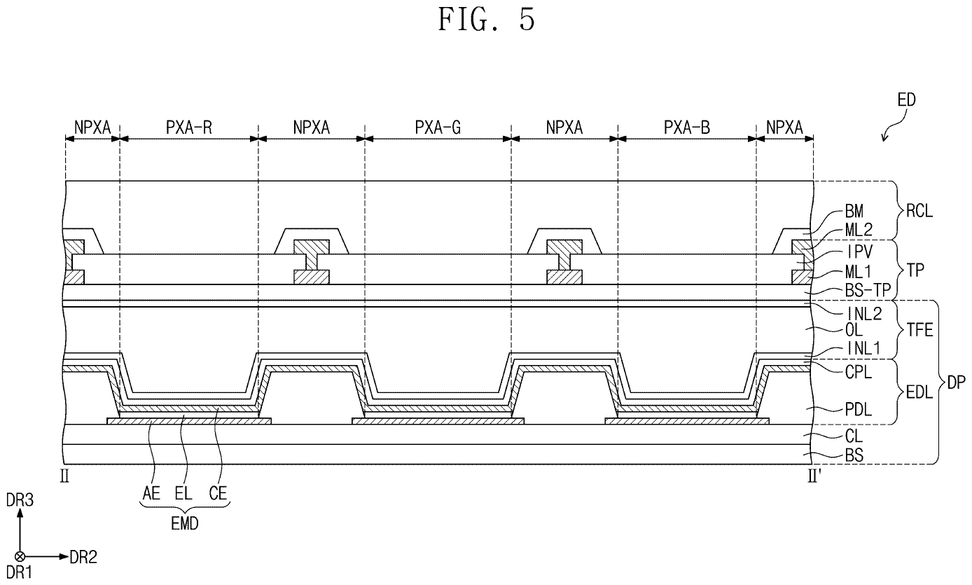

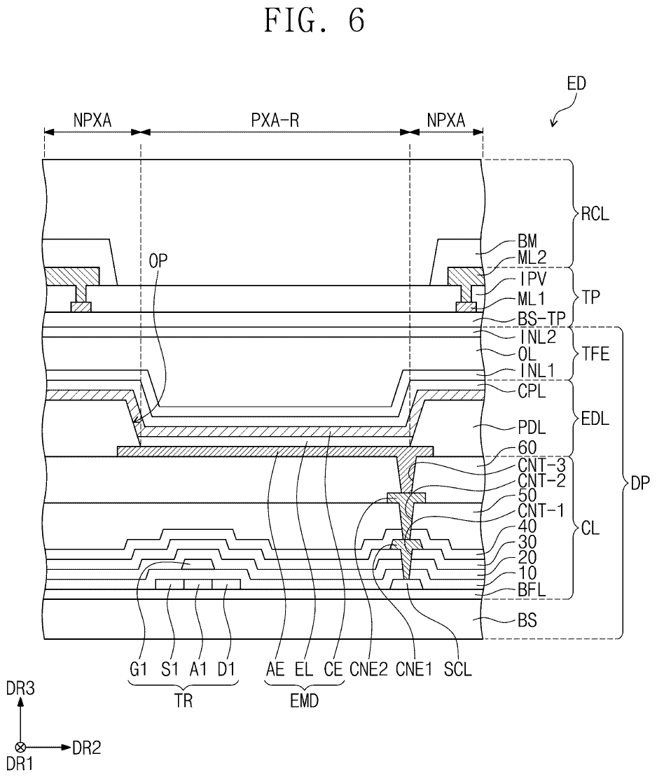

FIGS. 5 and 6 are cross-sectional views of a portion of the electronic device ED according to an embodiment of the present disclosure.

FIG. 5 is a cross-sectional view taken along a line II-II′ of FIG. 2. FIG. 5 shows the light emitting areas PXA-R, PXA-G, and PXA-B and the non-light-emitting area NPXA. FIG. 6 is a view showing the portion of the electronic device ED shown in FIG. 5. FIG. 6 shows the first light emitting area PXA-R and the non-light-emitting area NPXA.

Referring to FIGS. 5 and 6, the electronic device ED may include the display panel DP, the sensor layer TP disposed on the display panel DP, and the optical layer RCL disposed on the sensor layer TP.

The display panel DP may include the base layer BS, the circuit layer CL, the light emitting element layer EDL, and the encapsulation layer TFE, which are sequentially stacked.

The base layer BS may include the glass substrate, the metal substrate, or the polymer substrate, but is not limited thereto. According to an embodiment, the base layer BS may include the inorganic layer, the organic layer, or the composite material layer.

The base layer BS may have a single-layer or multi-layer structure. For instance, when the base layer BS has the multi-layer structure, the base layer BS may have a three-layer structure of a synthetic resin layer, an adhesive layer, and a synthetic resin layer. In particular, the synthetic resin layer may include a polyimide-based resin layer. In addition, the synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. In the present disclosure, the term “A-based resin” means that a functional group of “A” is included.

The circuit layer CL may be disposed on the base layer BS. The circuit layer CL may include a buffer layer BFL. The buffer layer BFL may enhance an adhesion between the base layer BS and the semiconductor pattern. The buffer layer BFL may include at least one of a silicon oxide layer, a silicon nitride layer, and a silicon oxynitride layer. As an example, the buffer layer BFL may have a structure in which two or more layers selected from the silicon oxide layer, the silicon nitride layer, and the silicon oxynitride layer are alternately stacked.

The semiconductor pattern may be disposed on the buffer layer BFL. The semiconductor pattern may include silicon. As an example, the semiconductor pattern may include amorphous silicon or polycrystalline silicon, but is not limited thereto. The semiconductor pattern may include metal oxide.

FIGS. 5 and 6 show only a portion of the semiconductor pattern, and the semiconductor pattern may be further disposed in other areas. The semiconductor pattern may be arranged according to a predetermined layout across the pixels. The semiconductor pattern may have different electrical properties depending on whether it is doped or not. The semiconductor pattern may include a first region with high conductivity and a second region with low conductivity. The first region may be doped with an N-type dopant or a P-type dopant. A P-type transistor may include a doped region doped with the P-type dopant, and an N-type transistor may include a doped region doped with the N-type dopant. The second region may be a non-doped region or may be doped at a concentration lower than the first region. The second region may be referred to as a channel area.

The first region may have a conductivity greater than that of the second region and may primarily serve as an electrode or a signal line. The second region may substantially correspond to an active area (or a channel) of a transistor. In other words, a portion of the semiconductor pattern may be the active area of the transistor, another portion of the semiconductor pattern may be a source or a drain of the transistor, and the other portion of the semiconductor pattern may be a connection electrode or a connection signal line.

Each of the pixels may have an equivalent circuit that includes a plurality of transistors, one capacitor, and the light emitting element, and the equivalent circuit of the pixels may be changed in various ways. FIG. 6 shows one transistor TR and a light emitting element EMD included in the pixel.

A source S1, an active A1, and a drain D1 of the transistor TR may be formed from the semiconductor pattern. The source S1 and the drain D1 may extend in opposite directions to each other from the active A1 in a cross-section. FIG. 6 shows a portion of a connection signal line SCL formed from the semiconductor pattern. Although not shown in figures, the connection signal line SCL may be electrically connected to the drain D1 of the transistor TR in a plane.

A first insulating layer 10 may be disposed on the buffer layer BFL. The first insulating layer 10 may commonly overlap the pixels and may cover the semiconductor pattern. The first insulating layer 10 may be an inorganic layer and/or an organic layer and may have a single-layer or multi-layer structure. The first insulating layer 10 may include at least one of aluminum oxide, titanium oxide, silicon oxide, silicon nitride, silicon oxynitride, zirconium oxide, and hafnium oxide. In the present embodiment, the first insulating layer 10 may have a single-layer structure of a silicon oxide layer. Additionally, both the first insulating layer 10 and other insulating layers within the circuit layer CL may be formed from inorganic and/or organic materials and may have either a single-layer or multi-layer structure. The inorganic material may include at least one of the above-mentioned materials, but is not limited thereto.

A gate G1 of the transistor TR may be disposed on the first insulating layer 10. The gate G1 may be a portion of a metal pattern. The gate G1 may overlap the active A1. The gate G1 may be used as a mask in a process of doping the semiconductor pattern. The gate G1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO) or indium zinc oxide (IZO), but is not limited thereto.

A second insulating layer 20 may be disposed on the first insulating layer 10 and may cover the gate G1. The second insulating layer 20 may be an inorganic layer and/or an organic layer and may have a single-layer or multi-layer structure, which includes at least one of a silicon oxide layer, a silicon nitride layer, and a silicon oxynitride layer.

A third insulating layer 30 may be disposed on the second insulating layer 20. The third insulating layer 30 may have a single-layer structure or a multi-layer structure, which includes at least one of a silicon oxide layer, a silicon nitride layer, and a silicon oxynitride layer.

A first connection electrode CNE1 may be disposed on the third insulating layer 30. The first connection electrode CNE1 may be connected to the connection signal line SCL via a contact hole CNT-1 defined through the first, second, and third insulating layers 10, 20, and 30.

A fourth insulating layer 40 may be disposed on the third insulating layer 30. The fourth insulating layer 40 may have a single-layer structure or a multi-layer structure, which includes at least one of a silicon oxide layer, a silicon nitride layer, and a silicon oxynitride layer.

A fifth insulating layer 50 may be disposed on the fourth insulating layer 40. The fifth insulating layer 50 may be an organic layer.

A second connection electrode CNE2 may be disposed on the fifth insulating layer 50. The second connection electrode CNE2 may be connected to the first connection electrode CNE1 via a contact hole CNT-2 defined through the fourth insulating layer 40 and the fifth insulating layer 50.

A sixth insulating layer 60 may be disposed on the fifth insulating layer 50 and may cover the second connection electrode CNE2. The sixth insulating layer 60 may be an organic layer.

The light emitting element layer EDL including the light emitting element EMD may be disposed on the circuit layer CL. The light emitting element layer EDL may include a pixel definition layer PDL and the light emitting element EMD including a functional layer EL disposed in an opening OP defined through the pixel definition layer PDL.

The light emitting element EMD may include a first electrode AE, the functional layer EL, and a second electrode CE. The functional layer EL may include a light emitting layer. In addition, the functional layer EL may further include a hole transport region and an electron transport region. The first electrode AE may be disposed on the sixth insulating layer 60. The first electrode AE may be connected to the second connection electrode CNE2 via a contact hole CNT-3 defined through the sixth insulating layer 60. The first electrode AE may include at least one selected from Ag, Mg, Cu, Al, Pt, Pd, Au, Ni, Nd, Ir, Cr, Li, Ca, LiF, Mo, Ti, W, In, Sn, and Zn, a combination of two or more compounds selected from the above-mentioned materials, a combination of two or more mixtures selected from the above-mentioned materials, or oxides of the above-mentioned metal materials.

In the case where the first electrode AE is the transmissive electrode, the first electrode AE may include a transparent metal oxide, such as indium tin oxide (ITO), indium zinc oxide (IZO), zinc oxide (ZnO) or indium tin zinc oxide (ITZO).

In the case where the first electrode AE is the semi-transmissive electrode or the reflective electrode, the first electrode AE may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof, e.g., a mixture of Ag and Mg. According to an embodiment, the first electrode AE may have a multi-layer structure of a reflective layer or a semi-transmissive layer, which includes the above-mentioned material, and a transparent conductive layer including indium tin oxide (ITO), indium zinc oxide (IZO), zinc oxide (ZnO), or indium tin zinc oxide (ITZO). As an example, the first electrode AE may have a three-layer structure of ITO/Ag/ITO, but is not limited thereto.

The pixel definition layer PDL may be disposed on the sixth insulating layer 60 and may cover a portion of the first electrode AE.

The opening OP may be defined through the pixel definition layer PDL. At least a portion of the first electrode AE may be exposed through the opening OP of the pixel definition layer PDL.

In the present embodiment, the light emitting area PXA-R may be defined to correspond to the portion of the first electrode AE, which is exposed through the opening OP. The non-light-emitting area NPXA may surround the light emitting area PXA-R. That is, the pixel definition layer PDL may define the light emitting areas PXA-R, PXA-G, and PXA-B. The light emitting areas PXA-R, PXA-G, and PXA-B may be distinguished from the non-light-emitting area NPXA by the pixel definition layer PDL. For example, the pixel definition layer PDL may define the boundaries of the light-emitting areas by separating them from surrounding non-light-emitting regions.

The pixel definition layer PDL may include a plurality of sub-pixel definition layers stacked in the thickness direction.

The pixel definition layer PDL may include a polymer resin. As an example, the pixel definition layer PDL may include a polyacrylate-based resin or a polyimide-based resin. In addition, the pixel definition layer PDL may further include an inorganic material in addition to the polymer resin. The pixel definition layer PDL may include a light absorbing material or may include a black pigment or a black dye. The pixel definition layer PDL including the black pigment or the black dye may be implemented as a black pixel definition layer. A carbon black may be used as the black pigment or the black dye, but is not limited thereto.

The pixel definition layer PDL may include an inorganic material. The pixel definition layer PDL may include silicon nitride, silicon oxide, or silicon oxynitride.

The functional layer EL may be disposed on the first electrode AE. In FIGS. 5 and 6, the functional layer EL may be disposed in the opening OP after being patterned, but is not limited thereto. The functional layer EL may overlap the light emitting areas PXA-R, PXA-G, and PXA-B and the non-light-emitting area NPXA.

The light emitting layer included in the functional layer EL may be disposed in each of the light emitting areas PXA-R, PXA-G, and PXA-B. The light emitting layer may be disposed in the light emitting areas PXA-R, PXA-G, and PXA-B. The light emitting layer may be divided into multiple portions and positioned in the respective light emitting areas (e.g., PXA-R, PXA-G and PXA-B), which are separated from one another by the pixel definition layer PDL. Each of the light emitting layers may emit a light having at least one of red, green, and blue colors, but is not limited thereto. The light emitting layer may be commonly provided over the light emitting areas PXA-R, PXA-G, and PXA-B and the non-light-emitting area NPXA. In this case, the light emitting layer may provide a blue light or a white light. The light emitting layer may include an organic light emitting material or a quantum dot material.

The hole transport region and the electron transport region may be commonly disposed in the light emitting areas PXA-R, PXA-G, and PXA-B and the non-light-emitting area NPXA. However, the present disclosure is not limited thereto, and according to an embodiment, the hole transport region and the electron transport region may be patterned to correspond to the light emitting areas PXA-R, PXA-G, and PXA-B.

The hole transport region may be disposed between the first electrode AE and the light emitting layer. The hole transport region may include a hole transport layer and may further include a hole injection layer. The electron transport region may be disposed between the light emitting layer and the second electrode CE. The electron transport region may include an electron transport layer and may further include an electron injection layer.

The light emitting layer may include a fluorescent or phosphorescent material that emits the red, green, or blue light. In addition, the light emitting layer may include a metal organic complex as its light emitting material. According to an embodiment, the light emitting layer may include a quantum dot as its light emitting material.

The second electrode CE may be disposed on the functional layer EL. The second electrode CE may have a single integrated shape and may be disposed in the light emitting areas PXA-R, PXA-G, and PXA-B and the non-light-emitting area NPXA as a common layer. The second electrode CE may include at least one selected from Ag, Mg, Cu, Al, Pt, Pd, Au, Ni, Nd, Ir, Cr, Li, Ca, LiF Mo, Ti, W, In, Sn, and Zn, a combination of two or more compounds selected from the above-mentioned materials, a combination of two or more mixtures selected from the above-mentioned materials, or oxides of the above-mentioned metal materials.

The second electrode CE may be a transmissive electrode, a semi-transmissive electrode, or a reflective electrode. In the case where the second electrode CE is the transmissive electrode, the second electrode CE may include a transparent metal oxide, e.g., indium tin oxide (ITO), indium zinc oxide (IZO), zinc oxide (ZnO), indium tin zinc oxide (ITZO), etc.

In the case where the second electrode CE is the semi-transmissive electrode or the reflective electrode, the second electrode CE may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, Yb, W, a compound thereof, or a mixture thereof, e.g., AgMg, AgYb, or MgYb. The second electrode CE may have a multi-layer structure of a reflective layer or a semi-transmissive layer, which includes the above-mentioned material, and a transparent conductive layer including indium tin oxide (ITO), indium zinc oxide (IZO), zinc oxide (ZnO), or indium tin zinc oxide (ITZO). As an example, the second electrode CE may include the above-mentioned metal materials, a combination of two or more metal materials selected from the above-mentioned metal materials, or oxides of the above-mentioned metal materials.

The light emitting element layer EDL may further include a capping layer CPL disposed on the light emitting element EMD. The capping layer CPL may be disposed on the second electrode CE. The capping layer CPL may have a single-layer or multi-layer structure.

The capping layer CPL may be an organic layer or an inorganic layer. As an example, in a case where the capping layer CPL includes an inorganic material, the inorganic material may include SiON, SiNₓ, SiO_{y}, an alkali metal compound, such as LiF, an alkaline earth metal compound, such as MgF₂, or the like. As an example, in a case where the capping layer CPL includes an organic material, the organic material may include α-NPD, NPB, TPD, m-MTDATA, Alq₃, CuPc, TPD15(N4,N4,N4′,N4′-tetra(biphenyl-4-yl) biphenyl-4,4′-diamine) or TCTA(4,4′,4″-Tris(carbazol-9-yl)triphenylamine), or may include an epoxy resin or an acrylate, such as methacrylate, but is not limited thereto.

The capping layer CPL may function as a buffer layer that protects the light emitting element EMD disposed under the capping layer CPL. The capping layer CPL may have a refractive index greater than or equal to about 1.6. As an example, the refractive index of the capping layer CPL may be about 1.9. When the capping layer CPL has the refractive index of about 1.9, a light extraction efficiency of the light emitting element layer EDL may be enhanced.

An upper surface of the light emitting element layer EDL may be defined by a shape of the pixel definition layer PDL and a shape of the light emitting element layer EDL. As an example, the upper surface of the light emitting element layer EDL may not be flat and may have a step difference. For example, the upper surface of the light emitting element layer EDL may be uneven and exhibit a step difference. A height of the upper surface of the light emitting element layer EDL from the base layer BS in the light emitting areas PXA-R, PXA-G, and PXA-B may be different from a height of the upper surface of the light emitting element layer EDL from the base layer BS in the non-light-emitting area NPXA. The step difference caused by the upper surface of the light emitting element layer EDL with a curve may be planarized by the encapsulation layer TFE. For example, the step difference resulting from the curved upper surface of the light emitting element layer EDL may be planarized by the encapsulation layer TFE.

The encapsulation layer TFE may be disposed on the light emitting element layer EDL. The encapsulation layer TFE may include a first inorganic layer INL1 disposed on the light emitting element layer EDL, an organic layer OL disposed on the first inorganic layer INL1, and a second inorganic layer INL2 disposed on the organic layer OL.

The encapsulation layer TFE including the first inorganic layer INL1 and second inorganic layer INL2 may protect the light emitting element layer EDL from moisture and oxygen. The encapsulation layer TFE including the organic layer OL may compensate for the step difference or curves caused by the light emitting element layer EDL. For example, the encapsulation layer TFE may compensate for step differences or surface irregularities caused by the light emitting element layer EDL. In addition, the encapsulation layer TFE including the organic layer OL may protect the light emitting element layer EDL from a foreign substance such as dust particles. The organic layer OL may have a thickness greater than or equal to about 0.2 μm and smaller than or equal to about 20 μm.

The first inorganic layer INL1 and the second inorganic layer INL2 may include at least one of silicon oxide, silicon nitride, and silicon oxynitride.

In an embodiment, the organic layer OL includes a covalent organic framework (COF). The covalent organic framework is a type of porous polymer that forms two-dimensional or three-dimensional structure through reactions between organic precursors, and refers to a porous and stable material formed through strong covalent bonds. In addition, the covalent organic framework may be a crystalline material. As an example, the covalent organic framework may be TFPT-BTAN-AO(1,3,5-triformylphloroglucinal-benzene-1,3,5-tricarbohydrazide-amidoxime).

The covalent organic framework may include a benzene ring. In addition, the covalent organic framework may include reactive groups to form an organic framework. As an example, the covalent organic framework may include an oxo group (═O), an amino group (—NH2), or a cyano group (—CN). As an example, the organic precursor that forms the covalent organic framework may be triphenylamine, benzidine, terephthalic dihydrazide, o-tolidine, 2,3,5,6-tetrafluoroterephthalaldehyde, [1,1′-biphenyl]-4,4′-dicarbaldehyde, 1,3,5-triformylphloroglucinal, 5,5′-diamino-2,2′-bipyridine, trimesoyl chloride, 2,6-diaminoanthraquinone, 1,3,5-triformylbenzene, 1,4-diaminobenzene, terephthaldicarboxal dehyde, 2,5-dihydroxyterephthaldehyde, 1,3,5-tris(4-aminophenyl)benzene, 2,5-dimethoxyterephthaldehyde, 2,4,6-tris(4-aminophenyl)-1,3,5-triazine, 4,4′,4″,4′″-(ethane-1,1,2,2,-tetrayl)tetraaniline, 1,3,5-tris(p-formylphenyl)benzene, p-phenylenediamine, or tetra(4-anilyl) methane.

When the organic layer OL includes the covalent organic framework, the organic layer OL may have lower dielectric constant properties than when the organic layer OL includes polymers instead of the covalent organic framework. In an embodiment, the organic layer OL has a dielectric constant greater than or equal to about 1.2 and smaller than or equal to about 2.5. Accordingly, a touch sensitivity of the sensor layer TP disposed on the encapsulation layer TFE may be enhanced.

In addition, as the organic layer OL includes the covalent organic framework, the organic layer OL may have excellent hardness and modulus. As an example, the modulus of the organic layer OL may be greater than or equal to about 0.01 GPa and smaller than or equal to about 4 GPa.

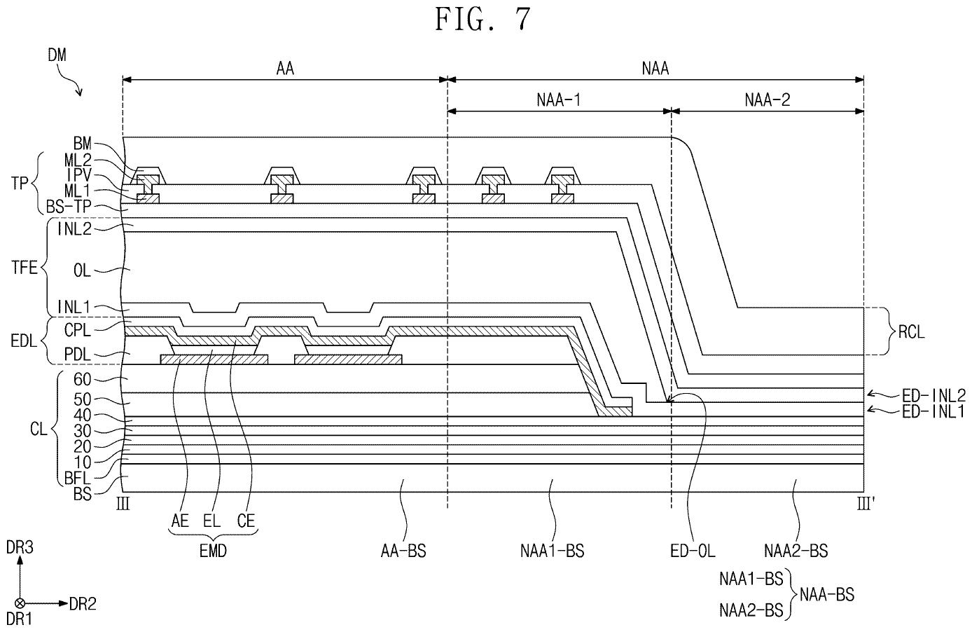

In addition, since the organic layer OL includes the covalent organic framework, the organic layer OL may be formed through a vapor deposition process. Accordingly, a dead space of the display panel DP and the electronic device ED may be reduced. The dead space will be described in detail with reference to FIG. 7.

The sensor layer TP may be disposed on the display panel DP. The sensor layer TP may be disposed directly on the second inorganic layer INL2. The sensor layer TP may be referred to as a sensor, an input sensing layer, or an input sensing panel. The sensor layer TP may include a sensing base layer BS-TP, a first conductive layer ML1, a sensing insulating layer IPV, and a second conductive layer ML2.

The sensing base layer BS-TP may be disposed directly on the display panel DP. The sensing base layer BS-TP may be an inorganic layer that includes at least one of silicon nitride, silicon oxynitride, and silicon oxide. According to an embodiment, the sensing base layer BS-TP may be an organic layer that includes an epoxy-based resin, an acrylic-based resin, or an imide-based resin. The sensing base layer BS-TP may have a single-layer structure or may have a multi-layer structure of layers stacked in the third direction DR3.

Each of the first and second conductive layers ML1 and ML2 may have a single-layer structure or a multi-layer structure of layers stacked in the third direction DR3. The conductive layer having the single-layer structure may include a metal layer or a transparent conductive layer. The metal layer may include molybdenum (Mo), silver (Ag), titanium (Ti), copper (Cu), aluminum (Al), or alloys thereof. The transparent conductive layer may include a transparent conductive oxide, such as indium tin oxide (ITO), indium zinc oxide (IZO), zinc oxide (ZnO), zinc peroxide (ZnO₂) or indium tin zinc oxide (ITZO). The transparent conductive layer may include a conductive polymer such as PEDOT, metal nanowire or graphene.

The conductive layer having the multi-layer structure may include metal layers. The metal layers may have a three-layer structure of titanium/aluminum/titanium. The conductive layer having the multi-layer structure may include at least one metal layer and at least one transparent conductive layer.

The sensing insulating layer IPV may be disposed between the first conductive layer ML1 and the second conductive layer ML2. The sensing insulating layer IPV may include an inorganic layer. The inorganic layer may include at least one of aluminum oxide, titanium oxide, silicon oxide, silicon nitride, silicon oxynitride, zirconium oxide, and hafnium oxide.

The sensing insulating layer IPV may include an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

The optical layer RCL may be disposed on the sensor layer TP. As an example, the optical layer RCL may be formed on the sensor layer TP through successive processes, but is not limited thereto.

The optical layer RCL may include a pigment or a dye. The optical layer RCL may include a plurality of filter portions that transmit light of different wavelength ranges. Each of the filter portions that transmit the light of different wavelength ranges may be disposed to correspond to each of the light emitting areas PXA-R, PXA-G, and PXA-B, which are separated by the non-light-emitting area NPXA.

The optical layer RCL may further include a black matrix BM. Materials for the black matrix BM are not particularly limited, provided they are capable of absorbing light. The black matrix BM may have a black color. The black matrix BM may include a black coloring agent. The black coloring agent may include a black dye or a black pigment. The black coloring agent may include a metal material, such as carbon black, chromium, or an oxide thereof.

The black matrix BM may cover the second conductive layer ML2 of the sensor layer TP. The black matrix BM may prevent external light from being reflected by the second conductive layer ML2.

However, the present disclosure is not limited thereto. For example, at least one of the sensor layer TP and the optical layer RCL may be omitted.

FIG. 7 is a cross-sectional view of a portion of a display module according to an embodiment of the present disclosure.

FIG. 7 is a cross-sectional view taken along a line III-III′ of FIG. 2. FIG. 7 shows the peripheral area NAA and a portion of the active area AA adjacent to the peripheral area NAA of the display module DM.

The display module DM may include the active area AA and the peripheral area NAA disposed outside the active area AA, and the peripheral area NAA may include a first peripheral area NAA-1 adjacent to the active area AA and a second peripheral area NAA-2 spaced apart from the active area AA. In the peripheral area NAA, an area where the organic layer OL is disposed may be defined as the first peripheral area NAA-1, and an area where the organic layer OL is absent may be defined as the second peripheral area NAA-2. A boundary between the first peripheral area NAA-1 and the second peripheral area NAA-2 may be defined as an edge ED-OL of the organic layer OL.

The first inorganic layer INL1 and the second inorganic layer INL2 may entirely cover the active area AA and may extend to the peripheral area NAA. When viewed in the plane, an area of the first inorganic layer INL1 may be substantially the same as an area of the second inorganic layer INL2. When viewed in the plane, the edge ED-INL1 of the first inorganic layer INL1 and an edge ED-INL2 of the second inorganic layer INL2 may be aligned, but the present disclosure is not limited thereto.

The organic layer OL may be covered by the second inorganic layer INL2. The organic layer OL may entirely cover the active area AA and may extend to the peripheral area NAA. When viewed in the plane, the edge ED-OL of the organic layer OL may be disposed inside the edge ED-INL1 of the first inorganic layer INL1 and the edge ED-INL2 of the second inorganic layer INL2.

When the organic layer OL includes the covalent organic framework, the organic layer OL may be formed through the vapor deposition process. As an example, the organic layer OL may be formed through a thermal evaporation process. When the organic layer OL is formed by vapor deposition, flow control at the edge ED-OL of the organic layer may be unnecessary. Accordingly, a dam structure may be unnecessary, allowing the peripheral area NAA, i.e., the dead space, to be reduced. In the present embodiment, the dead space may mean an area, i.e., the peripheral area NAA, other than the active area AA when viewed in the plane. As an example, the peripheral area NAA may have a width smaller than or equal to about 0.2 mm. In the present embodiment, the width of the peripheral area NAA may indicate a length in the second direction DR2 in FIG. 7.

Different from the present disclosure, when an inkjet process is used to form the organic layer with a material such as a monomer, it is necessary to control the flow of the organic layer. As a result, a dam structure is required, and this may lead to an increase the size of the dead space.

In the second peripheral area NAA-2, the first inorganic layer INL1 may be disposed directly on one layer extending from the active area AA. That is, the dam structure is absent from the second peripheral area NAA-2. As an example, the first inorganic layer INL1 of the second peripheral area NAA-2 may be disposed directly on the fourth insulating layer 40 of the circuit layer CL as shown in FIG. 7.

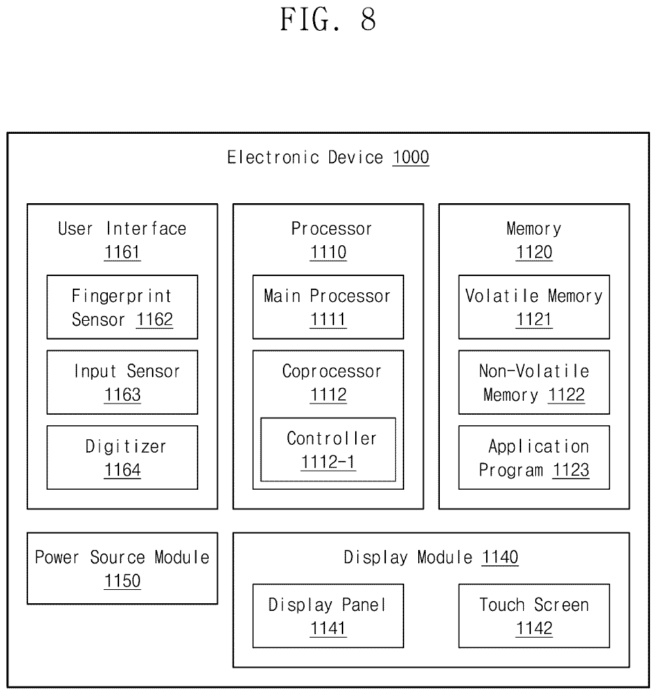

FIG. 8 is a diagram illustrating an electronic device according to an embodiment of the present invention. Referring to FIG. 8, the electronic device 1000 according to one embodiment of the present invention may output various information (e.g., images, text, music, etc.) through a display module 1140, which, for example, may correspond to the display device shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

Although various embodiments of the present disclosure have been described, it is understood that the present disclosure is not limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the attached claims.

What is claimed is:

1. A display panel comprising:
a base layer;
a circuit layer disposed on the base layer;
a light emitting element layer comprising a light emitting element and disposed on the circuit layer; and
an encapsulation layer disposed on the light emitting element layer and comprising a first inorganic layer, an organic layer disposed on the first inorganic layer, and a second inorganic layer disposed on the organic layer,
wherein the organic layer comprises a covalent organic framework.

2. The display panel of claim 1, wherein the organic layer has a dielectric constant greater than or equal to about 1.2 and smaller than or equal to about 2.5.

3. The display panel of claim 1, wherein the organic layer has a modulus greater than or equal to about 0.01 gigapascal (GPa) and smaller than or equal to about 4 GPa.

4. The display panel of claim 1, wherein the display panel comprises an active area where the light emitting element is disposed and a peripheral area surrounding the active area,
an edge of the organic layer is disposed outside the active area when viewed in a plane, and
the edge of the organic layer is disposed inside each of an edge of the first inorganic layer and an edge of the second inorganic layer when viewed in the plane.

5. The display panel of claim 1, wherein the organic layer has a thickness greater than or equal to about 0.2 micrometer (μm) and smaller than or equal to about 20 μm.

6. The display panel of claim 1, wherein each of the first and second inorganic layers comprises silicon oxide, silicon nitride, or silicon oxynitride.

7. The display panel of claim 1, wherein the organic layer is formed through a vapor deposition process.

8. The display panel of claim 1, wherein the covalent organic framework comprises a benzene ring.

9. The display panel of claim 1, wherein the covalent organic framework comprises an oxo group, an amino group, or a cyano group.

10. An electronic device comprising:
a display panel comprising a light emitting element; and
a sensor layer disposed on the display panel and configured to sense an external input, the display panel comprising:
a base layer;
a circuit layer disposed on the base layer;
a light emitting element layer comprising the light emitting element and disposed on the circuit layer; and
an encapsulation layer disposed on the light emitting element layer and comprising a first inorganic layer, an organic layer disposed on the first inorganic layer, and a second inorganic layer disposed on the organic layer,
wherein the organic layer comprises a covalent organic framework.

11. The electronic device of claim 10, wherein the organic layer has a dielectric constant greater than or equal to about 1.2 and smaller than or equal to about 2.5.

12. The electronic device of claim 10, wherein the organic layer has a modulus greater than or equal to about 0.01 gigapascal (GPa) and smaller than or equal to about 4 GPa.

13. The electronic device of claim 10, wherein the display panel comprises an active area where the light emitting element is disposed and a peripheral area surrounding the active area,
an edge of the organic layer is disposed outside the active area when viewed in a plane, and
the edge of the organic layer is disposed inside each of an edge of the first inorganic layer and an edge of the second inorganic layer when viewed in the plane.

14. The electronic device of claim 10, wherein the organic layer has a thickness greater than or equal to about 0.2 micrometer (μm) and smaller than or equal to about 20 μm.

15. The electronic device of claim 10, wherein each of the first and second inorganic layers comprises silicon oxide, silicon nitride, or silicon oxynitride.

16. The electronic device of claim 10, wherein the organic layer is formed through a vapor deposition process.

17. The electronic device of claim 10, wherein the covalent organic framework comprises a benzene ring.

18. The electronic device of claim 10, wherein the covalent organic framework comprises an oxo group, an amino group, or a cyano group.

19. The electronic device of claim 10, wherein the sensor layer is disposed directly on the second inorganic layer.

20. A display panel comprising:
a base layer;
a circuit layer disposed on the base layer;
a light emitting element layer comprising a light emitting element and disposed on the circuit layer; and
an encapsulation layer disposed on the light emitting element layer and comprising a first inorganic layer, an organic layer disposed on the first inorganic layer, and a second inorganic layer disposed on the organic layer,
wherein the organic layer comprises a porous organic material including a benzene ring and at least one of an oxo group, an amino group, or a cyano group.
